(19) United States
(12) Patent Application Publication
(10) Pub. No.: US 2026/0006789 A1
(43) Pub. Date: Jan. 1, 2026

(54) SEMICONDUCTOR DEVICE INCLUDING A TIERED STRUCTURE HAVING TAPERED FILL STRUCTURES

(71) Applicant: Micron Technology, Inc., Boise, ID (US)

(72) Inventors: Collin HOWDER, Boise, ID (US); Justin SHEPHERDSON, Meridian, ID (US); Christopher BREYFOGLE, Meridian, ID (US)

(21) Appl. No.: 19/193,757

(22) Filed: Apr. 29, 2025

Related U.S. Application Data
(60) Provisional application No. 63/665,104, filed on Jun. 27, 2024.

(51) Int. Cl. H10B 43/27; H10B 41/27

(52) U.S. Cl. CPC H10B 43/27; H10B 41/27

(57) ABSTRACT

Implementations described herein relate to various structures, integrated assemblies, and memory devices. In some implementations, a memory device includes a vertically-oriented contact pillar and a tiered structure proximate to the vertically-oriented contact pillar. The tiered structure includes an access line between two insulative layers and insulative fill structure. The insulative fill structure includes a tapered portion that is between the vertically-oriented contact pillar and the access line. The tapered portion may be between facing surfaces of ends of the insulative layers.

### CROSS-REFERENCE TO RELATED APPLICATION

This patent application claims priority to U.S. Provisional Patent Application No. 63/665,104, filed on Jun. 27, 2024, entitled “SEMICONDUCTOR DEVICE INCLUDING A TIERED STRUCTURE HAVING TAPERED FILLSTRUCTURES,” and assigned to the assignee hereof. The disclosure of the prior application is considered part of and is incorporated by reference into this patent application.

### TECHNICAL FIELD

The present disclosure generally relates to semiconductor devices and methods of forming semiconductor devices. For example, the present disclosure relates to a semiconductor device including a tiered structure having tapered fill structures.

### BACKGROUND

Memory devices provide data storage for electronic systems. Flash memory is a type of non-volatile memory, meaning that the memory retains data in the absence of a power supply. As an example, an electronic device may use flash memory in a solid state drive (SSD) for non-volatile storage of information, rather than a hard disk drive that uses magnetic disks for storage. NAND is a type of flash memory that has advantages over hard disk drives, such as lower erase times, lower write times, and less chip area per memory cell, which allows for more storage density and lower cost. The memory cells in NAND memory may be configured or formed in vertical stacks. This arrangement is sometimes called vertical NAND or three-dimensional (3D) NAND. 3D NAND arrangements enable a greater quantity of memory cells per chip surface area because of the vertical stacking of memory cells. 3D NAND arrangements also enable more options for the placement of cells to avoid interference and electron leakage, which can improve memory device performance. As the demand for storage capacity and performance increases, improvements in NAND architecture and improved methods for fabricating NAND memory are desirable.

### BRIEF DESCRIPTION OF THE DRAWINGS

FIG. 1 is a diagram illustrating an example of components included in a memory device described herein.

FIG. 2 is a diagram illustrating an example of a NAND memory array described herein.

FIG. 3 is a diagram illustrating an example of a 3D NAND memory array described herein.

FIGS. 4A and 4B are diagrammatic views related to an example memory device structure described herein.

FIGS. 5A and 5B are diagrammatic views related to example tapered structures described herein.

FIG. 6 is a flowchart of an example method of forming an integrated assembly or memory device including a tiered structure described herein.

FIG. 7 is a flowchart of another example method of forming an integrated assembly or memory device including a tiered structure described herein.

FIGS. 8A through 8H are diagrammatic views showing formation of portions of a tiered structure described at stages of an example process described herein.

### DETAILED DESCRIPTION

A semiconductor device (e.g., a NAND memory device) may include a tiered structure of alternating dielectric layers and conductive layers. The conductive layers may be used to form integrated circuitry of a memory device, such as access lines (e.g., word lines) that are used to select and activate rows of memory cells included in the memory device for data reading or data writing operations. The alternating dielectric layers and conductive layers may be adjacent to a contact pillar that supports the tiered structure and provides electrical coupling between a particular conductive layer (e.g., an access line) and a bit line. The contact pillar may be electrically isolated from other conductive layers (e.g., access lines) to allow selection of the particular access line, to which the contact pillar is electrically coupled, without selecting the other access lines.

To electrically isolate one or more of the conductive layers from the contact pillar, insulative fill structures may be formed between the one or more conductive layers and the contact pillar. The insulative fill structures may be formed by recessing temporary, sacrificial layers between the dielectric layers to form gaps that are subsequently backfilled with the insulative fill structures. The gaps may be between opposed, parallel surfaces that contribute to the gaps having a uniform profile or a step profile. During a deposition operation that backfills the gaps to form the insulative fill structures, constraints imposed upon the deposition operation by the opposed, parallel surfaces may cause formation of buried seams within the insulative fill structures near external edges of the insulative fill structures, which may lead to defects.

For example, if the contact pillar is formed in a cavity adjacent to the insulative fill structures, then the buried seams may be filled with a conductive material. As a result, a likelihood of electrical shorting defects across the contact pillar, the buried seams (e.g., filled with the conductive material), and the one or more conductive layers may increase, resulting in reduced quality or a reliability of the semiconductor device.

Some implementations described herein include a semiconductor device including a tiered structure with alternating conductive layers and dielectric layers. The tiered structure may be proximate to a contact pillar and may include insulative fill structures between the dielectric layers to isolate the conductive layers from the contact pillar. Techniques to form the tiered structure may include using a multi-layer structure including sacrificial layers alternating with the dielectric layers, recessing the sacrificial layers and, based on a difference in etch selectivity properties between the sacrificial layers and the dielectric layers, forming tapered cavities between the dielectric layers proximate the edges of the tiered structure. A deposition that deposits the insulative fill structures in the tapered cavities may form the insulative fill structures with a reduced likelihood of buried seams developing in the insulative fill structures near the edges of the tiered structure.

In this way, downstream operations that form a contact pillar may not breach a buried seam, thereby preventing deposition of a conductive material into the buried seam and reducing a likelihood of electrical shorting within the semiconductor device. As a result, a likelihood of electrical shorting defects between the contact pillar and the conductive layers may be reduced to improve a quality or a reliability of the semiconductor device.

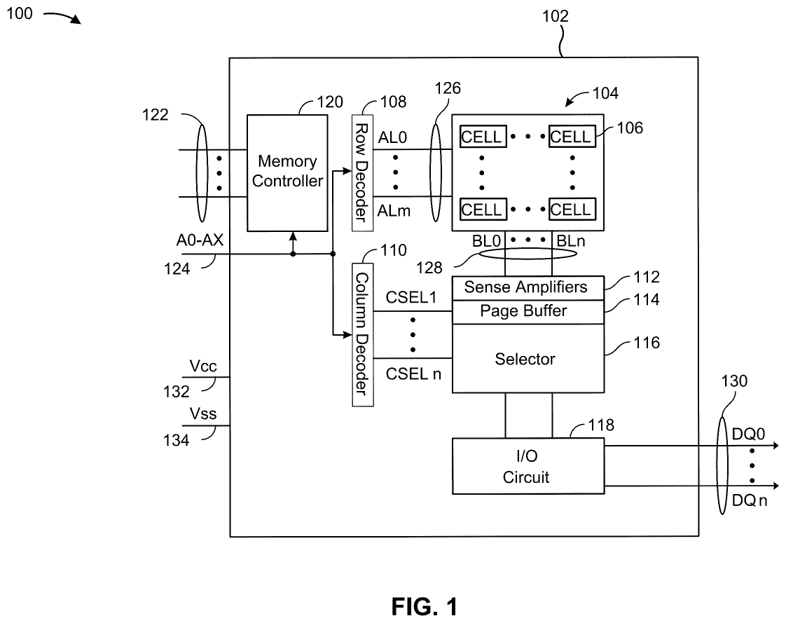

FIG. 1 is a diagram illustrating an example 100 of components included in a memory device 102 described herein. The memory device 102 may include a memory array 104 having multiple memory cells 106. The memory device 102 may include one or more components (e.g., circuits) to transmit signals to or perform memory operations on the memory array 104. For example, the memory device 102 may include a row decoder 108, a column decoder 110, one or more sense amplifiers 112, a page buffer 114, a selector 116, an input/output (I/O) circuit 118, and a memory controller 120.

The memory controller 120 may control memory operations of the memory device 102 according to one or more signals received via one or more control lines 122, such as one or more clock signals or control signals that indicate an operation (e.g., write, read, or erase) to be performed. The memory controller 120 may determine one or memory cells 106 upon which the operation is to be performed based on one or more signals received via one or more address lines 124, such as one or more address signals (shown as A0-AX). A host device external from the memory device 102 may control the values of the control signals on the control lines 122 or the address signals on the address line 124.

The memory device 102 may use access lines 126 (sometimes called word lines or row lines, and shown as AL0-ALm) and bit lines 128 (sometimes called digit lines, data lines, or column lines, and shown as BL0-BLn) to transfer data to or from one or more of the memory cells 106. For example, the row decoder 108 and the column decoder 110 may receive and decode the address signals (A0-AX) from the address line 124 and may determine which of the memory cells 106 are to be accessed based on the address signals. The row decoder 108 and the column decoder 110 may provide signals to those memory cells 106 via one or more access lines 126 and one or more bit lines 128, respectively.

For example, the column decoder 110 may receive and decode address signals into one or more column select signals (shown as CSEL1-CSELn). The selector 116 may receive the column select signals and may select data in the page buffer 114 that represents values of data to be read from or to be programmed into memory cells 106. The page buffer 114 may be configured to store data received from a host device before the data is programmed into relevant portions of the memory array 104, or the page buffer 114 may store data read from the memory array 104 before the data is transmitted to the host device. The sense amplifiers 112 may be configured to determine the values to be read from or written to the memory cells 106 using the bit lines 128. For example, in a selected string of memory cells 106, a sense amplifier 112 may read a logic level in a memory cell 106 in response to a read current flowing through the selected string to a bit line 128. The I/O circuit 118 may transfer values of data into or out of the memory device 102 (e.g., to or from a host device), such as into or out of the page buffer 114 or the memory array 104, using I/O lines 130 (shown as (DQ0-DQn)).

The memory controller 120 may generate or receive positive and negative supply signals, such as a supply voltage (Vcc) 132 and a negative supply (Vss) 134 (e.g., a ground potential), from an external source or power supply (e.g., an internal battery, an external battery, or an AC-to-DC converter).

As indicated above, FIG. 1 is provided as an example. Other examples may differ from what is described with regard to FIG. 1.

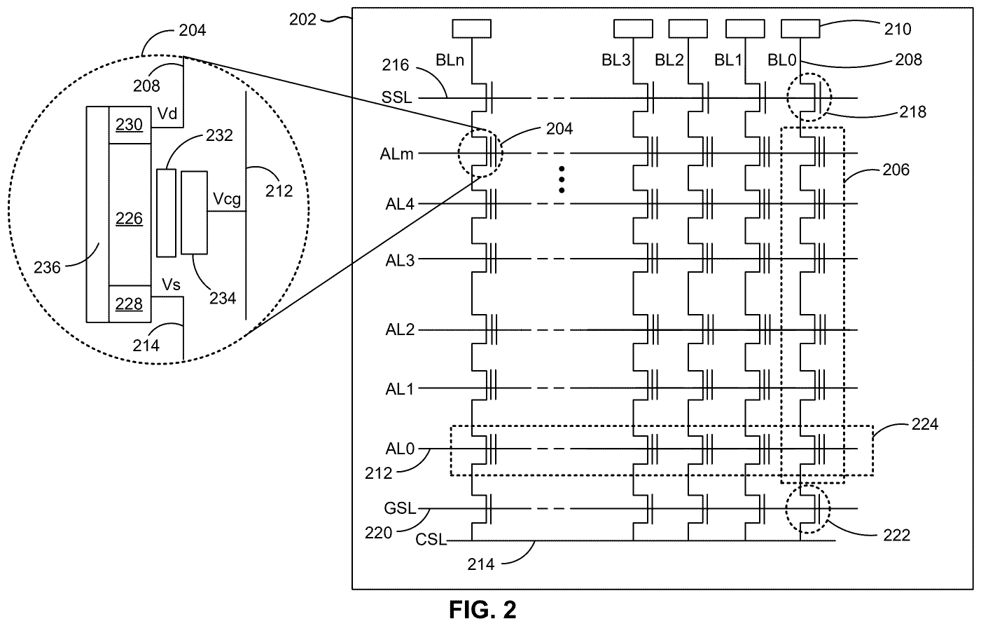

FIG. 2 is a diagram illustrating an example 200 of a NAND memory array 202 described herein. The NAND memory array 202 may correspond to the memory array 104 described above in connection with FIG. 1. The memory array 202 may be part of a three-dimensional stack of memory arrays, such as 3D NAND flash memory.

The memory array 202 includes multiple memory cells 204. A memory cell 204 may store an analog value, such as an electrical voltage or an electrical charge, that represents a data state (e.g., a digital value). The analog value and corresponding data state depend on a quantity of electrons trapped or present within a region of the memory cell 204 (e.g., in a charge trap, such as a floating gate), as described below.

A NAND string 206 (sometimes called a string) may include multiple memory cells 204 connected in series. A NAND string 206 is coupled to a bit line 208 (sometimes called a digit line or a column line, and shown as BL0-BLn). Data can be read from or written to the memory cells 204 of a NAND string 206 via a corresponding bit line 208 using one or more input/output (I/O) components 210 (e.g., an I/O circuit, an I/O bus, a page buffer, or a sensing component, such as a sense amplifier). Memory cells 204 of different NAND strings 206 (e.g., one memory cell 204 per NAND string 206) may be coupled with one another via access lines 212 (sometimes called word lines or row lines, and shown as AL0-ALm) that select which row (or rows) of memory cells 204 is affected by a memory operation (e.g., a read operation or a write operation).

A NAND string 206 may be connected to a bit line 208 at one end and a common source line (CSL) 214 at the other end. A string select line (SSL) 216 may be used to control respective string select transistors 218. A string select transistor 218 selectively couples a NAND string 206 to a corresponding bit line 208. A ground select line (GSL) 220 may be used to control respective ground select transistors 222. A ground select transistor 222 selectively couples a NAND string 206 to the common source line 214.

A “page” of memory (or “a memory page”) may refer to a group of memory cells 204 connected to the same access line 212, as shown by reference number 224. In some implementations (e.g., for single-level cells), the memory cells 204 connected to an access line 212 may be associated with a single page of memory. In some implementations (e.g., for multi-level cells), the memory cells 204 connected to an access line 212 may be associated with multiple pages of memory, where each page represents one bit stored in each of the memory cells 204 (e.g., a lower page that represents a first bit stored in each memory cell 204 and an upper page that represents a second bit stored in each memory cell 204). In NAND memory, a page is the smallest physically addressable data unit for a write operation (sometimes called a program operation).

In some implementations, a memory cell 204 is a floating-gate transistor memory cell. In this case, the memory cell 204 may include a channel 226, a source region 228, a drain region 230, a floating gate 232, and a control gate 234. The source region 228, the drain region 230, and the channel 226 may be on a substrate 236 (e.g., a semiconductor substrate). A memory device may store a data state in the memory cell 204 by charging the floating gate 232 to a particular voltage associated with the data state or to a voltage that is within a range of voltages associated with the data state. This results in a predefined amount of current flowing through the channel 226 (e.g., from the source region 228 to the drain region 230) when a specified read voltage is applied to the control gate 234 (e.g., by a corresponding access line 212 connected to the control gate 234). Although not shown, a tunnel oxide layer (or tunnel dielectric layer) may be interposed between the floating gate 232 and the channel 226, and a gate oxide layer (e.g., a gate dielectric layer) may be interposed between the floating gate 232 and the control gate 234. As shown, a drain voltage Vd may be supplied from a bit line 208, a control gate voltage Veg may be supplied from an access line 212, and a source voltage Vs may be supplied via the common source line 214 (which, in some implementations, is a ground voltage).

To write or program the memory cell 204, Fowler-Nordheim tunneling may be used. For example, a strong positive voltage potential may be created between the control gate 234 and the channel 226 (e.g., by applying a large positive voltage to the control gate 234 via a corresponding access line 212) while current is flowing through the channel 226 (e.g., from the common source line 214 to the bit line 208, or vice versa). The strong positive voltage at the control gate 234 causes electrons within the channel 226 to tunnel through the tunnel oxide layer and be trapped in the floating gate 232. These negatively charged electrons then act as an electron barrier between the control gate 234 and the channel 226 that increases the threshold voltage of the memory cell 204. The threshold voltage is a voltage required at the control gate 234 to cause current (e.g., a threshold amount of current) to flow through the channel 226. Fowler-Nordheim tunneling is an example technique for storing a charge in the floating gate, and other techniques, such as channel hot electron injection, may be used.

To read the memory cell 204, a read voltage may be applied to the control gate 234 (e.g., via a corresponding access line 212), and an I/O component 210 (e.g., a sense amplifier) may determine the data state of the memory cell 204 based on whether current passes through the memory cell 204 (e.g., the channel 226) due to the applied voltage. A pass voltage may be applied to all memory cells 204 (other than the memory cell 204 being read) in the same NAND string 206 as the memory cell 204 being read. For example, the pass voltage may be applied on each access line 212 other than the access line 212 of the memory cell 204 being read (e.g., where the read voltage is applied). The pass voltage is higher than the highest read voltage associated with any memory cell data states so that all of the other memory cells 204 in the NAND string 206 conduct, and the I/O component 210 can detect a data state of the memory cell 204 being read by sensing current (or lack thereof) on a corresponding bit line 208. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 234 to distinguish between the three or more data states and determine a data state of the memory cell 204.

To erase the memory cell 204, a strong negative voltage potential may be created between the control gate 234 and the channel 226 (e.g., by applying a large negative voltage to the control gate 234 via a corresponding access line 212). The strong negative voltage at the control gate 234 causes trapped electrons in the floating gate 232 to tunnel back across the oxide layer from the floating gate 232 to the channel 226 and to flow between the common source line 214 and the bit line 208. This removes the electron barrier between the control gate 234 and the channel 226 and decreases the threshold voltage of the memory cell 204 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some implementations, a block may be divided into multiple sub-blocks. A sub-block is a portion of a block and may include a subset of pages of the block or a subset of memory cells of the block.

As indicated above, FIG. 2 is provided as an example. Other examples may differ from what is described with regard to FIG. 2.

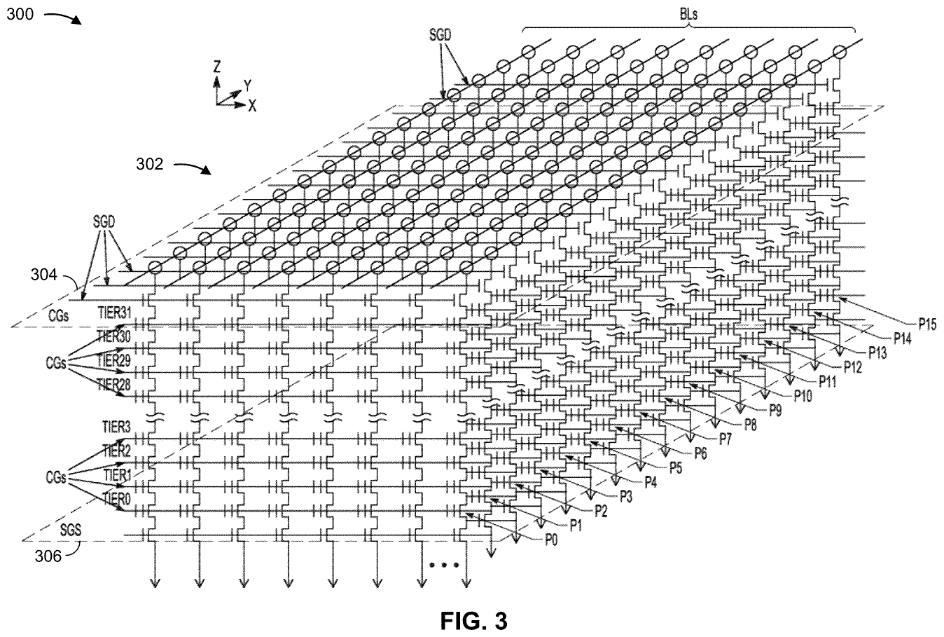

FIG. 3 is a diagram illustrating an example 300 of a 3D NAND memory array 302 described herein. The 3D NAND memory array 302 may correspond to the memory array 104 described above in connection with FIG. 1 or the NAND memory array 202 described above in connection with FIG. 2.

The 3D NAND memory array 302 includes multiple strings of memory cells.

A string includes multiple tiers of charge storage transistors stacked in a first direction, shown as the Z direction. The charge storage transistors are stacked source to drain from a source-side select gate (SGS) to a drain-side select gate (SGD). In the example 300 of FIG. 3, each string includes 32 tiers (shown as TIER0 through TIER31). In other examples, each string of memory cells may include a different quantity of tiers (e.g., 8 tiers, 16 tiers, 64 tiers, or 128 tiers). The memory cells of a particular string may share a common channel region, such as one formed in a respective pillar of semiconductor material (e.g., polysilicon) about which the string of memory cells is formed.

Along a second direction, shown as the Y direction, multiple strings of memory cells are connected along bit lines (BLs). For example, a first group of strings is coupled to a first bit line extending in the second direction, a second group of strings is coupled to a second bit line extending in the second direction, and so on.

Along a third direction, shown as the X direction, memory cells in the same tier but in different strings are arranged in memory pages (shown as P0 through P15). For example, a group of memory cells in a tier may be coupled to the same access line to form a page (or multiple pages, in the example of multi-level cells). Within a page, each tier represents a row of memory cells, and each string of memory cells represents a column. A block of memory cells can include multiple pages, such as 128 pages or 384 pages.

Each memory cell includes a control gate (CG) coupled to an access line, as described above in connection with FIG. 2. The access line collectively couples the control gates of memory cells in a specific tier or a portion of a tier. A tier in the 3D NAND memory array 302, can be accessed or controlled using an access line. For example, the 3D NAND memory array 302 may include a first level of semiconductor material 304 (e.g., polysilicon) that couples the control gates of each memory cell in TIER31. Similar respective levels of metal or semiconductor material may couple the control gates for each respective tier. As further shown, the 3D NAND memory array 302 may include a second level of semiconductor material 306 that couples the source-side select gates (SOS) of the array. Specific strings of memory cells in the 3D NAND memory array 302 can be accessed, selected, or controlled using a combination of bit lines and select gates, and specific memory cells at one or more tiers in the specific strings can be accessed, selected, or controlled using one or more access lines.

As indicated above, FIG. 3 is provided as an example. Other examples may differ from what is described with regard to FIG. 3. For example, the number of memory cells, strings, tiers, bit lines, access lines, or pages may be greater than or less than those shown in FIG. 3.

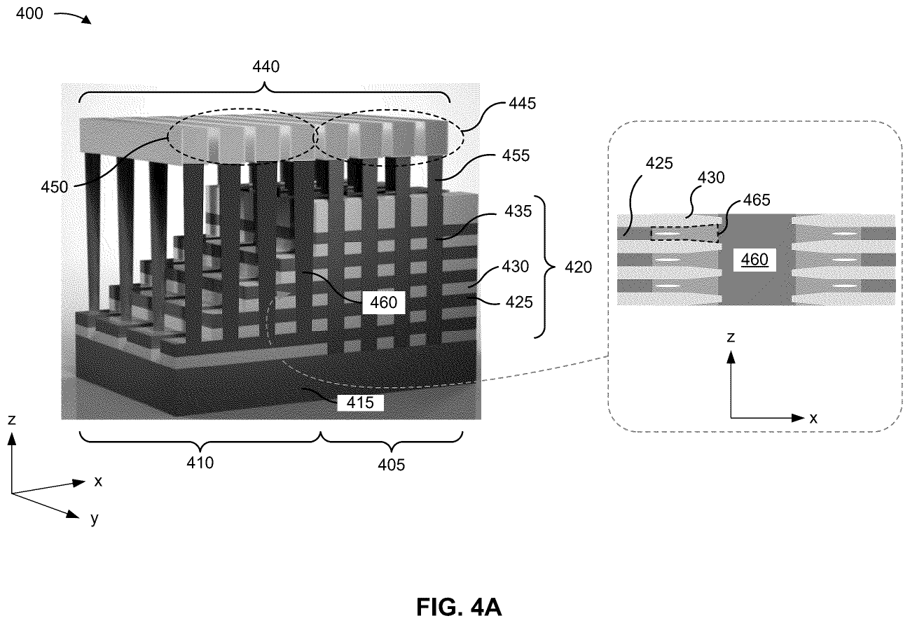

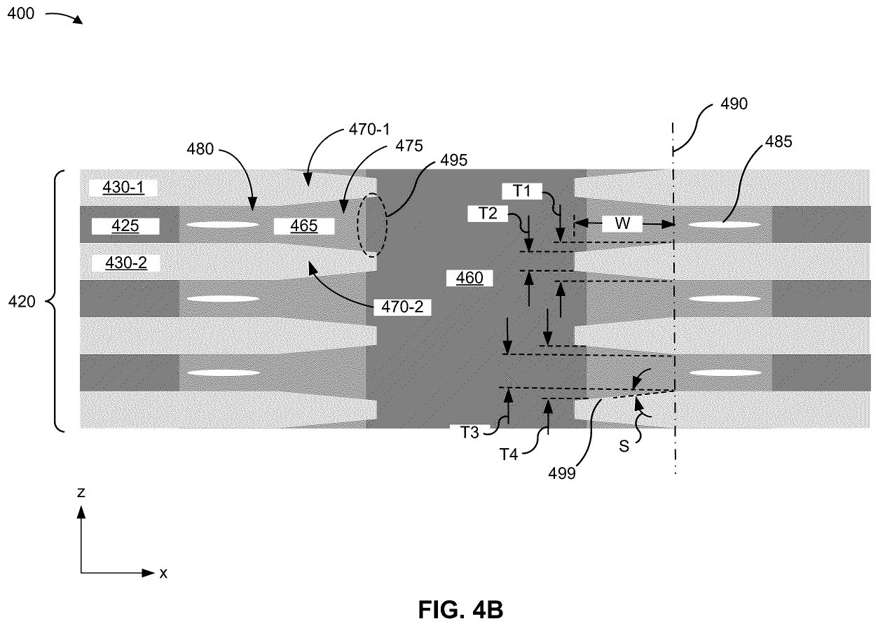

FIGS. 4A and 4B are diagrammatic views related to an example memory device structure 400 described herein. In some implementations, the memory device structure 400 corresponds to a structure of a three-dimensional (3D) NAND memory device.

As shown in the isometric section view on the left side of FIG. 4A, the memory device structure 400 includes a memory block region 405 and a staircase region 410. The memory block region 405 and the staircase region 410 each include portions of a substrate 415 and a tiered structure 420.

The substrate 415 may comprise, consist of, or consist essentially of semiconductive material. The semiconductive material may comprise, consist of, or consist essentially of silicon (e.g., polycrystalline silicon), among other examples. Alternatively, and in some implementations, the substrate 415 comprises, consists of, or consists essentially of silicon carbide, gallium nitride, or a type III-V element, among other examples.

The tiered structure 420 may include access lines 425 (sometimes called conductive layers herein) alternating with dielectric layers 430. In other words, the tiered structure 420 may include an arrangement of the access lines 425 and the dielectric layers 430 in a stack or layered structure, where the access lines 425 and the dielectric layers 430 alternate with one another within the stack. Each of the access lines 425 may be an electrical conductor and may comprise, consist of, or consist essentially of conductive material. As used herein, a conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide), among other examples. In some implementations, the access lines 425 may formed from conductive layers in the memory device structure 400.

Each of the dielectric layers 430 may be an electrical insulator and may comprise, consist of, or consist essentially of insulative material. As used herein, an insulative material may comprise, consist of, or consist essentially of an oxide (e.g., silicon oxide, aluminum oxide, or another suitable oxide material) or a nitride (e.g., silicon nitride aluminum nitride, or another suitable nitride material), among other examples. A dielectric layer 430 may electrically isolate an access line 425 (e.g., a first access line) that is above the dielectric layer 430 in the stack and another access line 425 (e.g., a second access line) that is below the dielectric layer 430 in the stack.

Within the memory block region 405, one or more pillar structures 435 may penetrate through the tiered structure 420. The pillar structures 435 may each include an annular distribution (e.g., layered rings) of conductive materials or insulative materials that form a channel or a storage cell of the memory device structure 400. The pillar structures 435 may be elongated structures that are vertically-oriented (e.g., orthogonal to the substrate 415) and include approximately round cross-sections or approximately rectangular cross sections, among other examples.

The memory device structure 400 may further include an array of conductive structures 440. The array of conductive structures 440 may include one or more conductive materials and be laterally disposed in at least one plane above the tiered structure 420.

The array of conductive structures 440 may include one or more bit lines 445 above the memory block region 405. The array of conductive structures 440 may further include connector lines 450 that correspond to control gate or source/select lines, among other examples. As shown in FIG. 4A, the bit lines 445 and the connector lines 450 are arranged in a parallel fashion in a common plane. However, and in other implementations, the bit lines 445 and the connector lines 450 may be arranged in an orthogonal fashion or distributed across multiple planes.

As shown in FIG. 4A, the memory device structure 400 may further include contact pillars 455 and contact pillars 460. The contact pillars 455 may be vertically-oriented (e.g., may be approximately orthogonal to the substrate 415), may support the bit lines 445, and may provide electrical coupling between the bit lines 445 and the pillar structures 435. The contact pillars 460 may be vertically-oriented, may support the connector lines 450, and may provide electrical coupling between the connector lines 450 and the access lines 425. The contact pillars 455 and the contact pillars 460 may each include one or more conductive materials as described above.

In some implementations, and for purposes of forming the contact pillars 460 in the staircase region 410 using a single etching step, the contact pillars 460 in the staircase region 410 may penetrate through treads of the staircase region 410 and through multiple underlying layers of the tiered structure 420.

To enable functionality of the memory device structure 400, each of the contact pillars 460 electrically couples with an access line 425. To prevent the contact pillars 460 from electrically coupling with other access lines 425 (e.g., underlying or buried conductive layers), and as shown in the detailed cross section in the right side of FIG. 4A, the tiered structure 420 may include dielectric fill structures 465 (e.g., between a contact pillar 460 and the underlying conductive layers adjacent to that contact pillar 460). Thus, the tiered structure 420 may include dielectric fill structures 465 that isolate one of more of the access lines 425 from the contact pillars 460. In some implementations, the tiered structure 420 that includes the dielectric fill structures 465 may surround a perimeter of at least one of the contact pillars 460.

A dielectric fill structure 465 may be between facing surfaces of proximate dielectric layers 430. The facing surfaces may be surfaces that are oriented towards one another (e.g., facing each other) across a specified separation, where the specified separation is filled with a dielectric fill structure 465. In some implementations, one or more surfaces of a dielectric fill structure 465 is in contact with the facing surfaces of the proximate dielectric layers 430, end surfaces of the access lines 425, or surfaces of the contact pillar 460. For example, and as show in FIG. 4B a first surface (e.g., a top surface) of the dielectric fill structure 465 is adjacent to (and in contact with) the dielectric layer 430-1 and a second surface (e.g., a bottom surface) of the dielectric fill structure 465 is adjacent to (and in contact with) the dielectric layer 430-2. Additionally, a third surface (e.g., a side surface) of the dielectric fill structure 465 is adjacent to (and in contact with) the end of the access line 425 and a fourth surface (e.g., another side surface) of the dielectric fill structure 465 is adjacent to (and in contact with) the contact pillar 460.

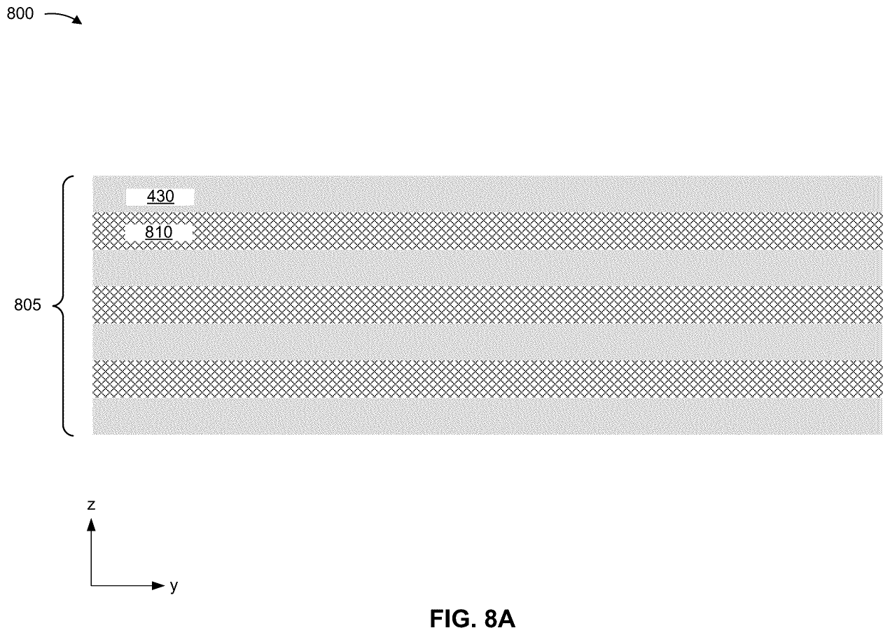

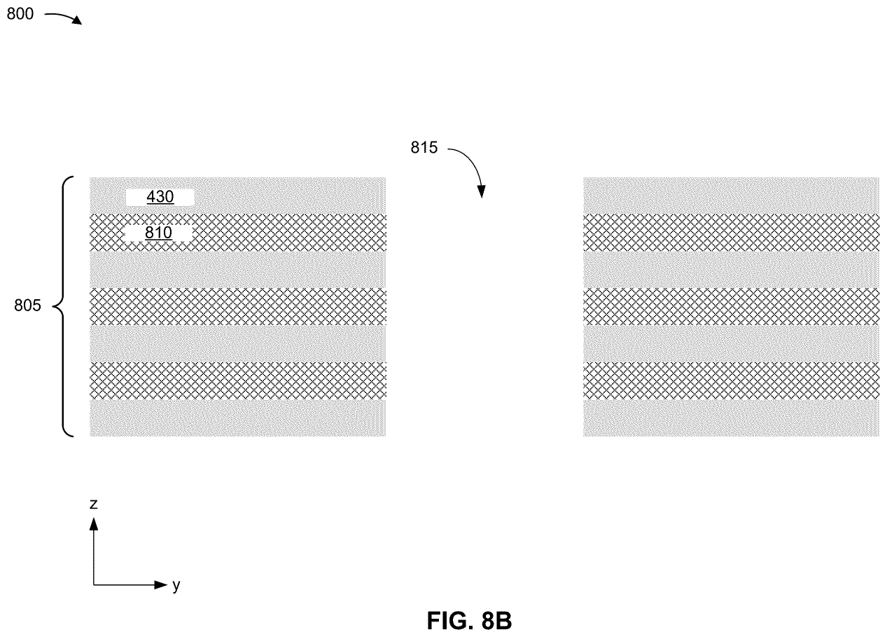

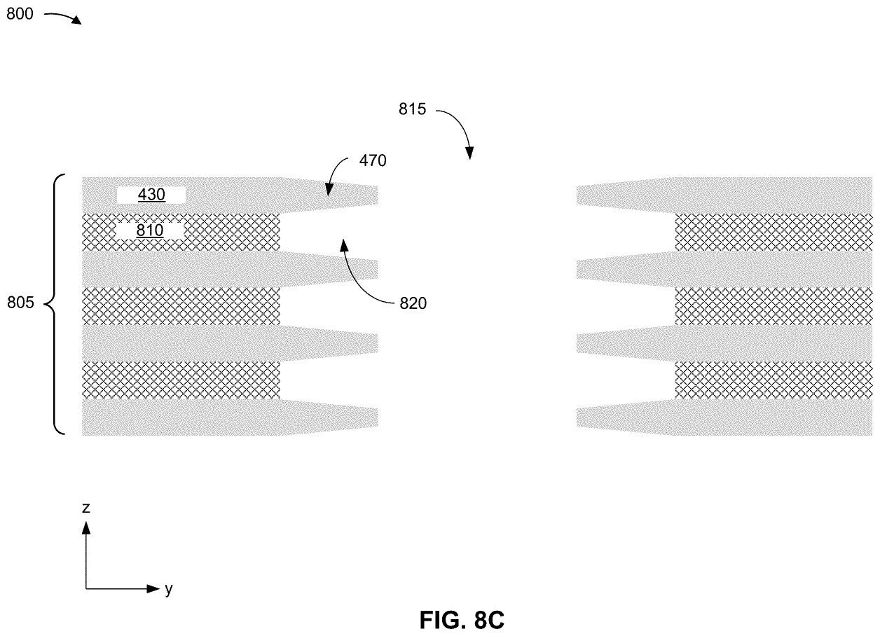

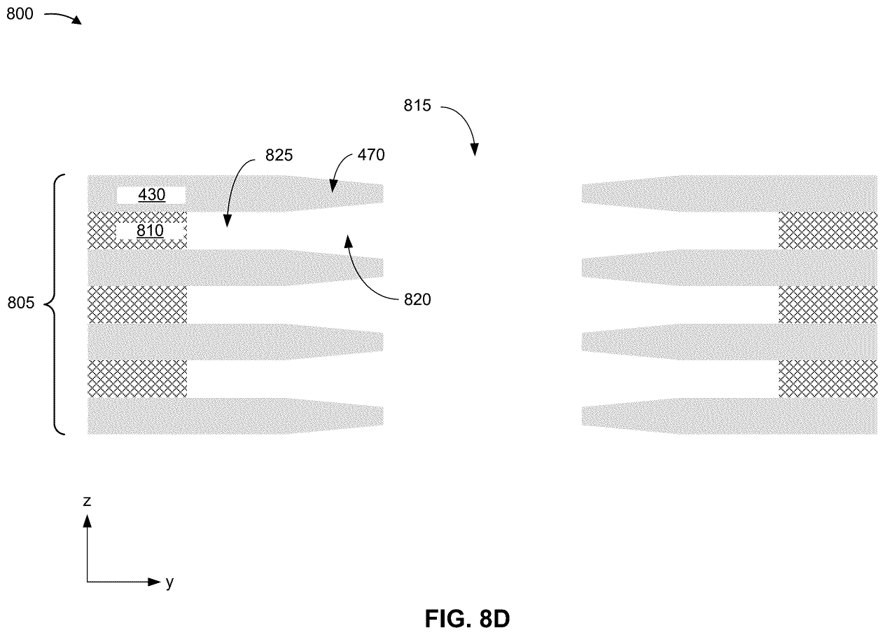

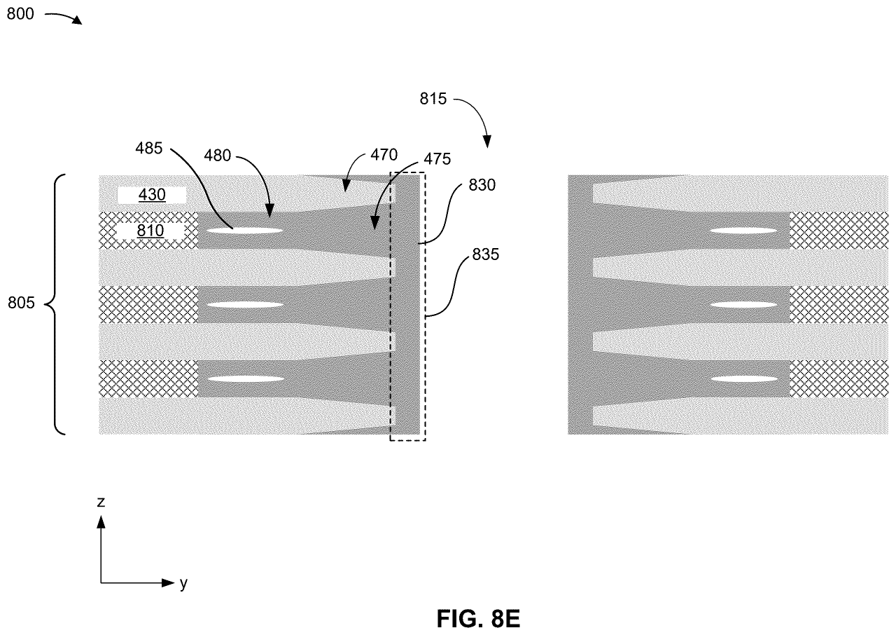

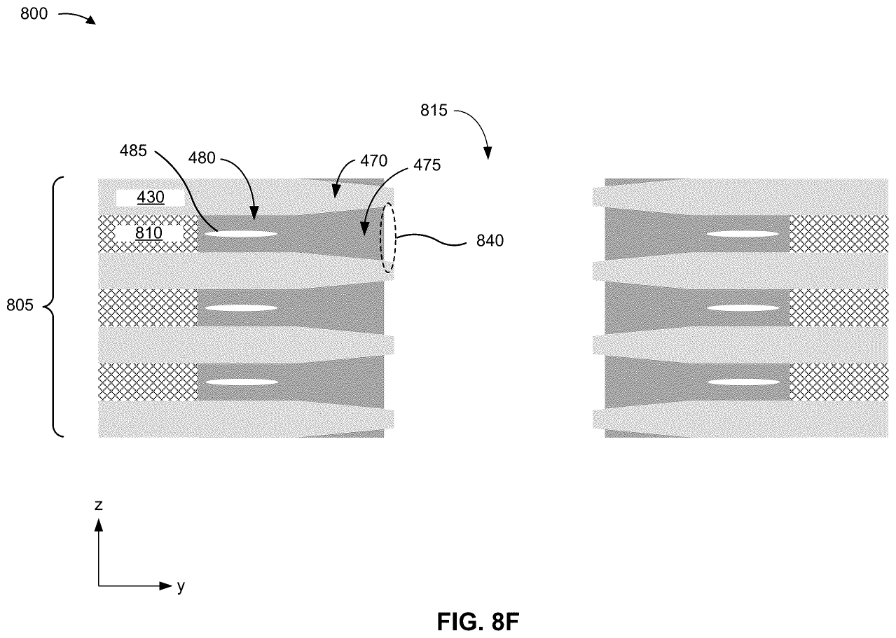

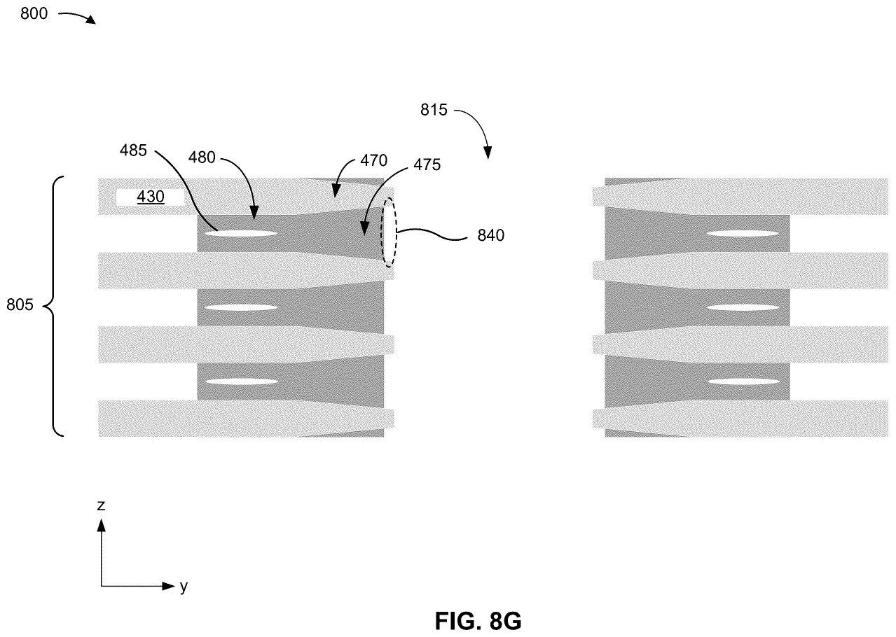

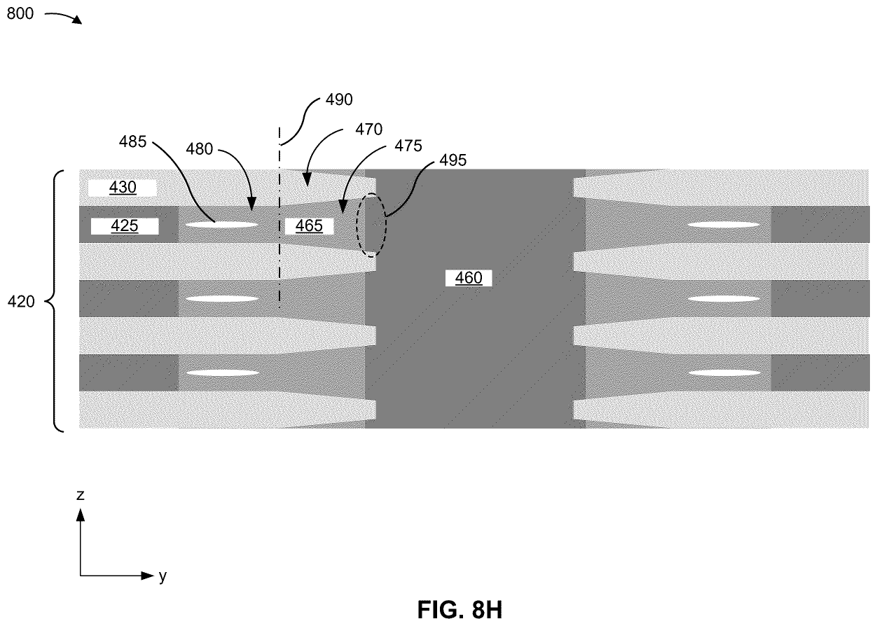

As shown in the magnified side section view in FIG. 4B, a dielectric layer 430 may include a tapered end 470 proximate to or adjacent to the contact pillar 460. The tapered end 470 may have a smaller thickness nearer to the contact pillar 460, and may have a greater thickness farther from the contact pillar 460. For example, a tapered end 470 may have a thickness T1 (e.g. a first thickness) at a boundary 490 that is not adjacent to the contact pillar 460, and maybe have a thickness T2 (e.g., a second thickness) adjacent to the contact pillar 460, where the thickness T2 is less than the thickness T1. As described in greater detail in connection with FIG. 8E, a thickness T2 that is less than the thickness T1 may enable using an atomic layer deposition (ALD) operation to form the tapered portion 475 without seams.

Additionally, or alternatively, a tapered end 470 may have a width W extending in a direction of a proximate access line 425, where a ratio of the width W to the thickness T1 (W:T1) is greater than or equal to approximately 1:4. If the ratio W:T1 is less than approximately 1:4, the buried seam 485 may extend across the boundary 490 and be too close to the contact pillar 460, thereby increasing a likelihood of electrical shorting between the contact pillar 460 and the access line 425. However, other values or ranges for the ratio W:T1 are within the scope of the present disclosure, such as greater than or equal to 1:3, greater than or equal to 1:35, greater than or equal to 1:4.5 or greater than or equal to 1:5.

In some implementations, a dielectric fill structure 465 may include a tapered portion 475. In some implementations, the dielectric fill structure 465 may include a uniform portion 480 (e.g., a portion having an approximately consistent thickness). The tapered portion 475 may have a greater thickness nearer to the contact pillar 460, and may have a smaller thickness farther from the contact pillar 460. For example, a tapered portion 475 may have a thickness T3 (e.g., a first thickness), nearer to a proximate access line 425 (and farther from the contact pillar 460), that is less than a thickness T4 (e.g., a second thickness) nearer the contact pillar 460 (and farther from the proximate access line 425). As described in greater detail in connection with FIG. 8E, a thickness T4 that is greater than the thickness T3 may enable using an atomic layer deposition (ALD) to form the tapered portion 475 without seams.

In some implementations, the dielectric layer 430 and the dielectric fill structure 465 include a same dielectric material. In such implementations, an interface (e.g., transition region) between the dielectric layer 430 and the dielectric fill structure 465 may exhibit impurities or defects that are introduced during a deposition operation that forms the dielectric fill structure 465. Further, a density of the dielectric material may vary along the interface (e.g., densities of the dielectric material may be different on opposing sides of the interface).

In some implementations, the difference in thickness between T3 and T4 may be included in a range of approximately 4 nanometers to approximately 6 nanometers. If the difference in thickness is less than approximately 4 nanometers, facing surfaces of the tapered ends 470 may be sufficiently parallel to cause formation of additional buried seams within a tapered portion 475, thereby increasing a likelihood of electrical shorting between a contact pillar 460 and an access line 425. If the difference in thickness is between approximately 4 nanometers and approximately 6 nanometers, facing surfaces of the tapered ends 470 may be sufficiently angled to prevent formation of additional buried seams within a tapered portion 475 while limiting formation of the buried seam 485 to within a uniform portion 480, thereby reducing a likelihood of electrical shorting between a contact pillar 460 and an access line 425. If the difference in thickness is greater than approximately 6 nanometers, the buried seam 485 may extend across the boundary 490 and into a tapered portion 475 to be too close to the contact pillar 460, thereby increasing a likelihood of electrical shorting between the contact pillar 460 and the access line 425). However, other values and ranges for the difference in thickness T4 relative to the thickness T3 are within the scope of the present disclosure, such as between 3, 3.5, 4.5, or 5 nanometers on the low end of the range and 6.5, 7, 7.5, or 8 nanometers on the high end of the range.

Additionally, or alternatively, one or more of the tapered ends 470 may have a sloped outer surface 499 extending from the boundary 490 in a direction towards the contact pillar 460. In some implementations, a gradient S of the sloped outer surface 499, relative to a plane extending from an interface between an access line 425 and a dielectric layer 430, may be included in a range of approximately 4% to approximately 6%. If the gradient S is less than approximately 4%, facing surfaces of the tapered ends 470 may be sufficiently parallel, thereby increasing a likelihood of formation or extension of a buried seam 485 into the tapered portion 475 (and increase a likelihood of electrical shorting between the contact pillars 460 and an access line 425). If the gradient S is between approximately 4% and approximately 6%, facing surfaces of the tapered ends 470 may be sufficiently angled to prevent formation or extension of the buried seam 485 into the tapered portion 475 while containing formation the buried seam 485 within the uniform portion 480 (e.g., and reduce a likelihood of electrical shorting between the contact pillars 460 and an access lines 425). If the gradient S is greater than approximately 6%, the buried seam 485 may extend across the boundary 275 and into the tapered portion 475 to be near external edges of the dielectric fill structure 465 (and increase a likelihood of electrical shorting between the contact pillar 460 and an access line 425). However, other values and ranges for gradient S are within the scope of the present disclosure, such as 2%, 2.5%, 3%, or 3.5% on the low end of the range and 6.5%, 7%, 7.5%, and 8% on the high end of the range.

As shown in FIG. 4B, a dielectric fill structure 465 may include a buried seam 485 (e.g., discontinuities, fissures, or cracks). In some implementations, the buried seam 485 is between an access line 425 and a boundary 490 that corresponds to an inflection point at which a tapered end 470 of a dielectric layer 430 begins (e.g., within a uniform portion 480). In other words, the buried seam 485 may be sufficiently distanced from edges of the tiered structure 420, excluded from the tapered end 470, or substantially distant from the contact pillar 460 to prevent formation of a conductive material in the buried seam 485. However, in some implementations a dielectric fill structure 465 (including the uniform portion 480) may be seamless.

In some implementations, a contact pillar 460 may include a protrusion 495. As shown in FIG. 4B, the protrusion 495 may extend towards a tapered portion 475 between tapered ends 470 of proximate dielectric layers 430. However, in some implementations, the contact pillar 460 may be free of the protrusion 495 (e.g., the contact pillar 460 may not include the protrusion 495 and outer surfaces of the contact pillar 460 may be “flush” with end surfaces of the dielectric layers 430 and the dielectric fill structure 465).

As indicated above, FIGS. 4A and 4B are provided as an example. Other examples may differ from what is described with respect to FIGS. 4A and 4B.

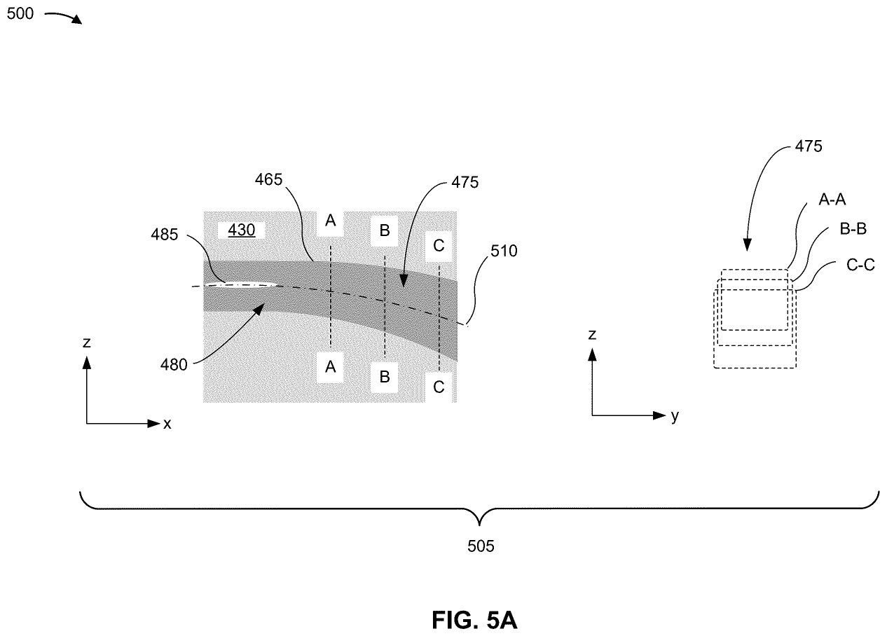

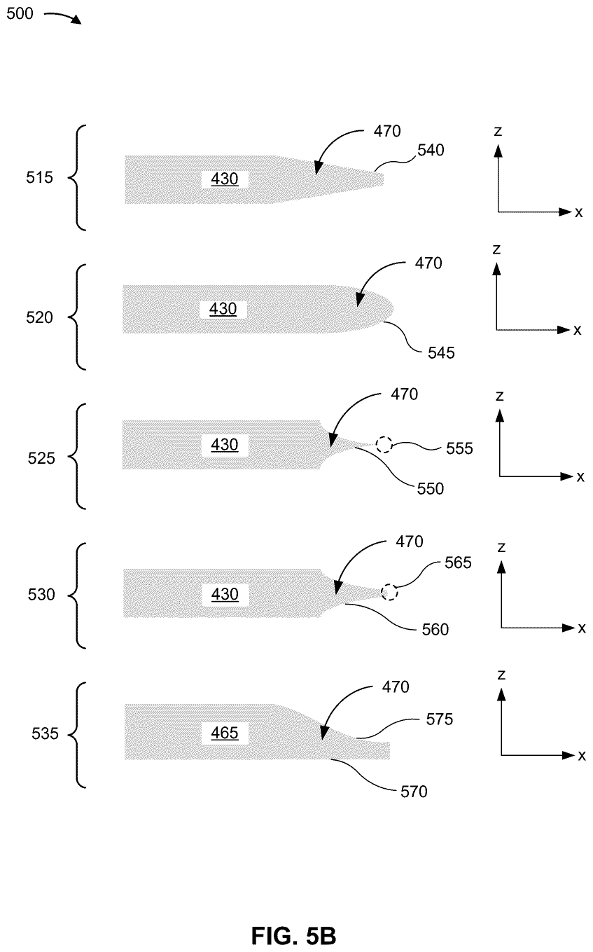

FIGS. 5A and 5B are diagrammatic views related to example implementations 500 of tapered structures described herein. FIG. 5A includes details related to an example implementation of the tapered portions 475 of the dielectric fill structures 465, and FIG. 5B includes details related to example implementations of the tapered ends 470 of the dielectric layers 430.

FIG. 5A shows an example implementation 505 of a dielectric fill structure 465 including a curved tapered portion 475. As shown in the side view (e.g., the z-x plane) of FIG. 5A, the tapered portion 475 may traverse a curved axis 510, with substantially equal halves of the tapered portion 475 on either side of the curved axis 510. In other words, the tapered ends 470 may be curvilinearly tapered, or bounded by curved lines, with an increasing thickness from a first end of the tapered portion 475 to a second end of the tapered portion 475.

For example, and as shown in the end view (e.g., the z-y plane) of FIG. 5A, cross-sectional areas of the tapered portion 475 may be graduating cross-sectional areas that increase as the tapered portion 475 extends away from the uniform portion 480. For example, the cross-sectional area along section line C-C may be greater than the cross-sectional area along section line B-B. Additionally, or alternatively, the cross-sectional area along section line B-B may be greater than the cross-sectional area along section line A-A.

FIG. 5B shows example implementations 515, 520, 525, 530, and 535 of a tapered end 470 of a dielectric layer 430. The example implementations 515 through 535 may be formed as a result of differences in operations and/or parameters used by semiconductor manufacturing equipment during formation of the tapered end 470. Additionally, or alternatively, the example implementations 515-535 may be formed as a result of different densities of materials used to form the tapered end 470.

As shown in the side view of implementation 515, a tapered end 470 may include opposing surfaces 540 that are substantially linear.

As shown in the side view of implementation 520, a tapered end 470 may include opposing surfaces 545 that include convex curvatures. In other words, the opposing surface 545 may bow outwards from the dielectric layer 430.

As shown in the side view of implementation 525, a tapered end 470 may include opposing surfaces 550 that include concave curvatures. In other words, the opposing surfaces 550 may bow inwards towards the dielectric layer 430. Further, and as shown in the side view of implementation 525, the opposing surfaces 550 may converge to form a pointed tip 555.

As shown in the side view of implementation 530, a tapered end 470 may include opposing surfaces 560 that include concave curvatures. However, and in contrast to implementation 525, the tapered end 470 may have a truncated tip 565 (e.g., a “blunt” tip) with a thickness that satisfies a threshold, such as 1 nanometer, 2 nanometers, 3 nanometers, 4 nanometers, or the like.

As shown in the side view of implementation 535, a tapered end 470 may include opposing surfaces 570 and 575, where the surface 570 is substantially linear and the surface 575 includes a curvature. In some implementations, the curvature of the surface 575 may include multiple inflection points.

As described above, FIGS. 5A and 5B are provided as one or more examples. Other examples may differ from what is described with regard to FIGS. 5A and 5B.

As described in connection with FIG. 1 through FIG. 5B, and in some implementations, an apparatus (e.g., a semiconductor device including the memory device structure 400) includes a vertically-oriented contact pillar (e.g., the contact pillar 460) and a tiered structure (e.g., tiered structure 420) proximate to the vertically-oriented contact pillar. The tiered structure 420 includes an access line (e.g., the access lines 425) between two insulative layers (e.g., between the dielectric layer 430-1 and the dielectric layer 430-2) and an insulative fill structure (e.g., the dielectric fill structure 465). The insulative fill structure includes a tapered portion (e.g., the tapered portion 475) that is between the vertically-oriented contact pillar and the access line. In some implementations, the tapered portion is between facing surfaces of ends of the insulative layers (e.g., between the tapered end 470-1 and the tapered end 470-2).

Furthermore, in some implementations, a semiconductor device (e.g., the memory device structure 400) includes a vertically-oriented conductive structure (e.g., the contact pillars 460) and a tiered structure (e.g., the tiered structure 420) proximate the vertically-oriented conductive structure. The tiered structure includes a first dielectric layer (e.g., the dielectric layer 430-1) having a first tapered end (e.g., the tapered end 470-1) that extends laterally toward the vertically-oriented conductive structure and a second dielectric layer (e.g., the dielectric layer 430-2) having a second tapered end (e.g., the tapered end 470-2) that extends laterally toward the vertically-oriented conductive structure. The tiered structure includes a conductive layer (e.g., the access line 425) that is between the first dielectric layer and the second dielectric layer. The tiered structure includes a dielectric fill structure (e.g., the dielectric fill structure 465) that is between the vertically-oriented conductive structure and the conductive layer.

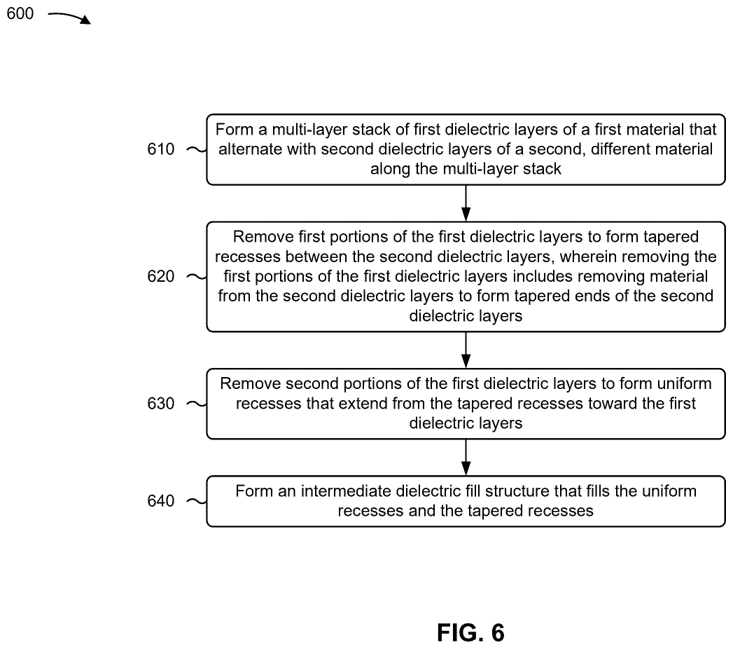

As described in greater detail in connection with FIGS. 6, 7, 8A-8H, and elsewhere herein, techniques to form a tiered structure (e.g., the tiered structure 420) may include using a multi-layer structure including alternating sacrificial layers and dielectric layers (e.g., the dielectric layers 430), recessing the sacrificial layers and, based on a differences in etch selectivity properties between the sacrificial layers and the dielectric layers, forming tapered cavities between the dielectric layers proximate the edges of the tiered structure. A deposition operation that deposits insulative fill structures (e.g., the dielectric fill structure 465) in the tapered cavities may form the insulative fill structures with a reduced likelihood of buried seams (e.g., the buried seam 485) developing in the insulative fill structures near the edges of the tiered structure.

In this way, downstream operations that form a contact pillar (e.g., the contact pillar 460) may not breach the buried seam thereby preventing deposition of a conductive material into the buried seam and reducing a likelihood of electrical shorting within the semiconductor device. As a result, a likelihood of electrical shorting defects between the contact pillar and the conductive layers may be reduced to improve a quality or a reliability of the semiconductor device.

FIG. 6 is a flowchart of an example method 600 of forming an integrated assembly or memory device including a tiered structure (e.g., the tiered structure 420) described herein. In some implementations, and as described in greater detail in connection with FIGS. 8A-8H, one or more process blocks of FIG. 6 may be performed by various semiconductor manufacturing equipment.

As shown in FIG. 6, the method 600 may include forming a multi-layer stack of first dielectric layers of a first material alternating with second dielectric layers along the multi-layer stack (e.g., the dielectric layers 430) of a second, different material (block 610). As further shown in FIG. 6, the method 600 may include removing first portions of the first dielectric layers to form tapered recesses between the second dielectric layers, wherein removing the first portions of the first dielectric layers includes removing material from the second dielectric layers to form tapered ends (e.g., the tapered end 470) of the second dielectric layers (block 620). As further shown in FIG. 6, the method 600 may include removing second portions of the first dielectric layers to form uniform recesses that extend from the tapered recesses toward the first dielectric layers (block 630). As further shown in FIG. 6, the method 600 may include forming an intermediate dielectric fill structure that fills the uniform recesses and the tapered recesses (block 640).

The method 600 may include additional aspects, such as any single aspect or any combination of aspects described below or in connection with one or more other methods described elsewhere herein.

In a first aspect, forming the intermediate dielectric fill structure includes forming a tapered portion (e.g., the tapered end 470) that is free of a buried seam (e.g., the buried seam 485).

In a second aspect, alone or in combination with the first aspect, forming the intermediate dielectric fill structure includes forming a uniform portion (e.g., the uniform portion 480) that includes a buried seam (e.g., the buried seam 485).

In a third aspect, alone or in combination with one or more of the first and second aspects, removing the first portions of the first dielectric layers and the second portions of the first dielectric layers includes removing the first portions using a first etchant having a first selectivity for the first material, and removing the second portions using a second etchant having a second selectivity for the first material, wherein the second selectivity is greater than the first selectivity.

In a fourth aspect, alone or in combination with one or more of the first through third aspects, the first etchant having the first selectivity for the first material has a third selectivity for the second, different material, wherein the third selectivity is less than the first selectivity.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the tiered structure 420, an integrated assembly that includes the tiered structure 420, any part described herein of the tiered structure 420, or any part described herein of an integrated assembly that includes the tiered structure 420. For example, the method 600 may include forming one or more of the access lines 425, the dielectric layers 430, the contact pillar 460, the dielectric fill structure 465, the tapered end 470, the tapered portion 475, or the uniform portion 480.

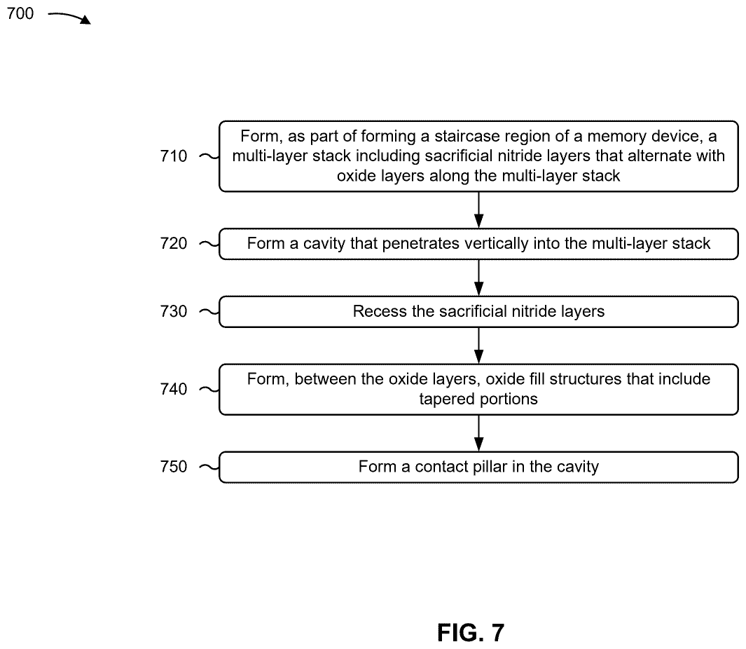

FIG. 7 is a flowchart of an example method 700 of forming an integrated assembly or memory device including a tiered structure (e.g., the tiered structure 420) described herein. In some implementations, and as described in greater detail in connection with FIGS. 8A-8H, one or more process blocks of FIG. 7 may be performed by various semiconductor manufacturing equipment.

As shown in FIG. 7, the method 700 may include forming, as part of forming a staircase region (e.g., the staircase region 410) of a memory device, a multi-layer stack including sacrificial nitride layers alternating with oxide layers (e.g., the dielectric layers 430) along the multi-layer stack (block 710). As further shown in FIG. 7, the method 700 may include forming a cavity that penetrates vertically into the multi-layer stack (block 720). As further shown in FIG. 7, the method 700 may include recessing the sacrificial nitride layers (block 730). As further shown in FIG. 7, the method 700 may include forming, between the oxide layers, oxide fill structures (the dielectric fill structure 465) that include tapered portions (e.g., the tapered end 470) (block 740). As further shown in FIG. 7, the method 700 may include forming a contact pillar (e.g., the contact pillar 460) in the cavity (block 750).

The method 700 may include additional aspects, such as any single aspect or any combination of aspects described below or in connection with one or more other methods described elsewhere herein.

In a first aspect, forming the oxide fill structures includes forming an intermediate oxide fill structure that includes a sidewall over ends of the oxide layers, and removing the sidewall.

In a second aspect, alone or in combination with the first aspect, forming the contact pillar includes forming protrusions (e.g., the protrusion 495) that extend toward the tapered portions.

In a third aspect, alone or in combination with one or more of the first and second aspects, recessing the sacrificial nitride layers includes using an etching operation that forms tapered recesses between ends of the oxide layers.

In a fourth aspect, alone or in combination with one or more of the first through third aspects, forming the oxide fill structures includes forming the oxide fill structures using an atomic layer deposition operation that forms a seamless oxide fill in the tapered recesses.

In a fifth aspect, alone or in combination with one or more of the first through fourth aspects, the etching operation is a first etching operation and recessing the sacrificial nitride layers further includes using a second etching operation to form uniform recesses that extend from the tapered recesses.

In a sixth aspect, alone or in combination with one or more of the first through fifth aspects, the method 700 includes forming the oxide fill structures using an atomic layer deposition operation that forms an oxide fill (e.g., the uniform portion 480) having discontinuities (e.g., the buried seam 485) in at least one of the uniform recesses.

Although FIG. 7 shows example blocks of the method 700, in some implementations, the method 700 may include additional blocks, fewer blocks, different blocks, or differently arranged blocks than those depicted in FIG. 7. In some implementations, the method 700 may include forming may include forming the tiered structure 420, an integrated assembly that includes the tiered structure 420, any part described herein of the tiered structure 420, or any part described herein of an integrated assembly that includes the tiered structure 420. For example, the method 700 may include forming one or more of the access lines 425, the dielectric layers 430, the contact pillar 460, the dielectric fill structure 465, the tapered end 470, the tapered portion 475, or the uniform portion 480.

FIGS. 8A through 8H are diagrammatic views showing formation of portions of a tiered structure (e.g., the tiered structure 420) described at stages of an example process 800 described herein. In some implementations, the process 800 described below in connection with FIGS. 8A through 8H may correspond to the method 600, one or more blocks of the method 600, the method 700, or one or more blocks of the method 700. However, the process described below is an example, and other example processes may be used to form the tiered structure, an integrated assembly that includes the tiered structure, or one or more parts of an integrated assembly including the interconnect array structure.

As shown in FIG. 8A, the process 800 includes forming a multi-layer stack 805 of dielectric layers 430 (e.g., oxide layers) that alternate with sacrificial layers 810 (e.g., sacrificial nitride layers) along the multi-layer stack 805. In some implementations, techniques to form one or more layers of the multi-layer stack 805 include a semiconductor manufacturing tool (e.g., a deposition tool) performing a deposition operation.

As shown in FIG. 8B, the process 800 includes forming a cavity 815 into or through the multi-layer stack 805. In some implementations, techniques to form the cavity 815 include a semiconductor manufacturing tool (e.g., an etch tool) performing a dry etch operation.

As shown in FIG. 8C, the process 800 includes recessing the sacrificial layers 810 to form a tapered cavity 820 in the multi-layer stack 805 and form a tapered end 470. In some implementations, techniques to form the tapered cavity 820 and the tapered end 470 includes a semiconductor manufacturing tool (e.g., an etch tool) performing a wet etch operation (e.g., a first lateral wet etch operation) to simultaneously form the tapered cavity 820 and the tapered end 470. To simultaneously form the tapered cavity 820 and the tapered end 470, the wet etch operation may use an etchant having a greater selectivity (e.g., etch rate) for a material of the sacrificial layers 810 than for a material of the dielectric layers 430. For example, and in a case where the sacrificial layers 810 include a nitride material and the dielectric layers 430 include an oxide material, the etchant may include a hot blend (e.g., a first hot blend) of hydrofluoric (HF) acid diluted with water, where a temperature of the hot blend is approximately 65 degrees Celsius (° C.) and a concentration of the HF acid to the water may be approximately 1:500.

As shown in FIG. 8D, and in some implementations, the process 800 includes further recessing the sacrificial layers 810 to form a uniform cavity 825 that extends from the tapered cavity 820 further into the multi-layer stack 805. In some implementations, techniques to form the uniform cavity 825 include a semiconductor manufacturing tool (e.g., an etch tool) performing a wet etch operation (e.g., a second lateral wet etch operation) to form the uniform cavity 825. Relative to the etchant described in connection with FIG. 8C used to form the tapered cavity 820, an etchant used to form the uniform cavity 825 may have an increased selectivity for the material of the sacrificial layers 810. For example, and in the case where the sacrificial layers 810 include the nitride material and the dielectric layers 430 include the oxide material, the etchant having the increased selectivity may include a hot blend (e.g., a second hot blend) of HF acid diluted with water, where a temperature of the hot blend is approximately 80° C. and the concentration of the HF acid to the water is approximately 1:2000.

In some implementations, and as described in connection with FIGS. 8C and 8D, selecting different temperatures or concentrations of an etchant may alter a selectivity of the material of the sacrificial layers 810 versus a selectivity of the material of dielectric layers 430. In other words, different combinations of temperatures or concentrations of an etchant may be selected to alter (e.g., “tune”) an angle of the tapered end 470, a depth of the tapered cavity 820, a thickness of the uniform cavity 825, or a depth of the uniform cavity 825. Further, and in some implementations, recessing the sacrificial layers 810 may include a single etch operation (e.g., to extend the tapered cavity 820 to a greater depth and eliminate the second etch operation that forms the uniform cavity 825).

As shown in FIG. 8E, the process 800 includes forming an intermediate dielectric fill structure 830. In some implementations, techniques to form the intermediate dielectric fill structure 830 include a semiconductor manufacturing tool (e.g., a deposition tool) performing a deposition operation. As an example, the deposition operation may be an atomic layer deposition operation that deposits oxide to form the intermediate dielectric fill structure 830. As shown in FIG. 8E, the intermediate dielectric fill structure 830 includes the tapered portion 475, the uniform portion 480, and a sidewall 835 that is over or on ends of the dielectric layers 430. In some implementations, and as shown in FIG. 8E, the intermediate dielectric fill structure 830 includes a buried seam 485 within the uniform portion 480. However, and in some implementations, the intermediate dielectric fill structure 830 (e.g., the uniform portion 480) may be free of the buried seam 485 (e.g., exclude the buried seam 485).

As shown in FIG. 8F, the process 800 includes removing the sidewall 835 from the intermediate dielectric fill structure 830. In some implementations, techniques to remove the sidewall 835 include a semiconductor manufacturing tool (e.g., an etch tool) performing an etch operation (e.g., a wet etch operation) that removes the sidewall 835. As shown in FIG. 8F, and in some implementations, the etch operation forms a recess 840 that extends into the tapered ends 470.

As shown in FIG. 8G, the process 800 includes removing remaining portions of the sacrificial layers 810. In some implementations, techniques to remove the remaining portions of the sacrificial layers 810 include a semiconductor manufacturing tool (e.g., an etch tool) performing an etch operation (e.g., a dry etch operation) that exhumes the remaining portions of the sacrificial layers from between the dielectric layers 430.

As shown in FIG. 8H, the process 800 includes forming the access lines 425 and the contact pillar 460. In some implementations, techniques to form the access lines 425 and the contact pillar 460 include a semiconductor manufacturing tool (e.g., a deposition tool) performing one or more deposition operations (e.g., one or more chemical vapor deposition operations or physical vapor deposition operations) to deposit one or more conductive materials to form the access lines 425 and the contact pillar 460.

As indicated above, the process 800 described in connection with FIGS. 8A through 8H is provided as an example. Other examples may differ from what is described with respect to FIGS. 8A through 8H.

In some implementations, a semiconductor device includes a vertically-oriented conductive structure; a tiered structure proximate the vertically-oriented conductive structure, comprising: a first dielectric layer having a first tapered end that extends laterally toward the vertically-oriented conductive structure; a second dielectric layer having a second tapered end that extends laterally toward the vertically-oriented conductive structure; a conductive layer that is between the first dielectric layer and the second dielectric layer; and a dielectric fill structure that is between the vertically-oriented conductive structure and the conductive layer.

In some implementations, an apparatus includes a vertically-oriented contact pillar; a tiered structure proximate to the vertically-oriented contact pillar, comprising: an access line between two insulative layers; and an insulative fill structure, comprising: a tapered portion that is between the vertically-oriented contact pillar and the access line, wherein the tapered portion is between facing surfaces of ends of the insulative layers.

In some implementations, a method includes forming a multi-layer stack of first dielectric layers of a first material that alternate with second dielectric layers of a second, different material along the multi-layer stack, removing first portions of the first dielectric layers to form tapered recesses between the second dielectric layers, wherein removing the first portions of the first dielectric layers includes removing material from the second dielectric layers to form tapered ends of the second dielectric layers; removing second portions of the first dielectric layers to form uniform recesses that extend from the tapered recesses toward the first dielectric layers; and forming an intermediate dielectric fill structure that fills the uniform recesses and the tapered recesses.

In some implementations, a method includes forming, as part of forming a staircase region of a memory device, a multi-layer stack including sacrificial nitride layers that alternate with oxide layers along the multi-layer stack; forming a cavity that penetrates vertically into the multi-layer stack; recessing the sacrificial nitride layers; forming, between the oxide layers, oxide fill structures that include tapered portions; and forming a contact pillar in the cavity.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, or assembly in use or operation in addition to the orientations depicted in the figures. A structure or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” All ranges described herein are inclusive of numbers at the ends of those ranges, unless specifically indicated otherwise.

Even though particular combinations of features are recited in the claims or disclosed in the specification, these combinations are not intended to limit the disclosure of implementations described herein. Many of these features may be combined in ways not specifically recited in the claims or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device, comprising:
a vertically-oriented conductive structure;
a tiered structure proximate the vertically-oriented conductive structure, comprising:
a first dielectric layer having a first tapered end that extends laterally toward the vertically-oriented conductive structure;
a second dielectric layer having a second tapered end that extends laterally toward the vertically-oriented conductive structure;
a conductive layer that is between the first dielectric layer and the second dielectric layer; and
a dielectric fill structure that is between the vertically-oriented conductive structure and the conductive layer.

2. The semiconductor device of claim 1, wherein the dielectric fill structure is in contact with facing surfaces of the first dielectric layer and the second dielectric layer.

3. The semiconductor device of claim 1, wherein the dielectric fill structure is in contact with a surface of the conductive layer facing the vertically-oriented conductive structure.

4. The semiconductor device of claim 1, further comprising:
a buried seam within the dielectric fill structure between the conductive layer and a boundary corresponding to an inflection point at which the first tapered end and the second tapered end begin.

5. The semiconductor device of claim 1, wherein the dielectric fill structure is seamless between the vertically-oriented conductive structure and a boundary corresponding to an inflection point at which the first tapered end and the second tapered end begin.

6. The semiconductor device of claim 1, wherein the first tapered end comprises:
a first thickness at a boundary corresponding to an inflection point at which the first tapered end begins,
a second thickness at a tip of the tapered end,
wherein the second thickness is less than the first thickness, and
a width between the boundary and the tip,
wherein a ratio of the width to the first thickness is greater than approximately 1:4.

7. An apparatus, comprising:
a vertically-oriented contact pillar;
a tiered structure proximate to the vertically-oriented contact pillar, comprising:
an access line between two insulative layers; and
an insulative fill structure, comprising:
a tapered portion that is between the vertically-oriented contact pillar and the access line,
wherein the tapered portion is between facing surfaces of ends of the insulative layers.

8. The apparatus of claim 7, wherein the vertically-oriented contact pillar comprises:
a protrusion that extends toward the tapered portion and between the ends of the insulative layers.

9. The apparatus of claim 7, wherein a first thickness of the tapered portion nearer the access line is less than a second nearer the vertically-oriented contact pillar.

10. The apparatus of claim 7, wherein the tapered portion comprises:
a sloped outer surface relative to a plane extending from an interface between the access line and an insulative layer of the two insulative layers,
wherein a gradient of the sloped outer surface relative to the plane is included in a range of approximately 4% to approximately 6%.

11. The apparatus of claim 7, wherein the tapered portion is between the access line and the vertically-oriented contact pillar.

12. The apparatus of claim 7, wherein the vertically-oriented contact pillar, the tiered structure, and the insulative fill structure are part of a staircase region of a NAND memory device.

13. The apparatus of claim 7, wherein the tiered structure and the insulative fill structure surround a perimeter of the vertically-oriented contact pillar.

14. A method, comprising:
forming a multi-layer stack of first dielectric layers of a first material that alternate with second dielectric layers of a second, different material along the multi-layer stack,
removing first portions of the first dielectric layers to form tapered recesses between the second dielectric layers,
wherein removing the first portions of the first dielectric layers includes removing material from the second dielectric layers to form tapered ends of the second dielectric layers;
removing second portions of the first dielectric layers to form uniform recesses that extend from the tapered recesses toward the first dielectric layers; and
forming an intermediate dielectric fill structure that fills the uniform recesses and the tapered recesses.

15. The method of claim 14, wherein forming the intermediate dielectric fill structure includes:
forming a tapered portion that is free of a buried seam.

16. The method of claim 14, wherein forming the intermediate dielectric fill structure includes:
forming a uniform portion that includes a buried seam.

17. The method of claim 14, wherein removing the first portions of the first dielectric layers and the second portions of the first dielectric layers includes:
removing the first portions using a first etchant having a first selectivity for the first material, and
removing the second portions using a second etchant having a second selectivity for the first material,
wherein the second selectivity is greater than the first selectivity.

18. The method of claim 17, wherein the first etchant having the first selectivity for the first material has a third selectivity for the second, different material,
wherein the third selectivity is less than the first selectivity.

19. A method, comprising:
forming, as part of forming a staircase region of a memory device, a multi-layer stack including sacrificial nitride layers that alternate with oxide layers along the multi-layer stack;
forming a cavity that penetrates vertically into the multi-layer stack;
recessing the sacrificial nitride layers;
forming, between the oxide layers, oxide fill structures that include tapered portions; and
forming a contact pillar in the cavity.

20. The method of claim 19, wherein forming the oxide fill structures includes:
forming an intermediate oxide fill structure that includes a sidewall over ends of the oxide layers, and
removing the sidewall.

21. The method of claim 19, wherein forming the contact pillar includes:
forming protrusions that extend toward the tapered portions.

22. The method of claim 19, wherein recessing the sacrificial nitride layers includes:
using an etching operation that forms tapered recesses between ends of the oxide layers.

23. The method of claim 22, wherein forming the oxide fill structures includes:
forming the oxide fill structures using an atomic layer deposition operation that forms a seamless oxide fill in the tapered recesses.

24. The method of claim 22, wherein the etching operation is a first etching operation and recessing the sacrificial nitride layers further includes:
using a second etching operation to form uniform recesses that extend from the tapered recesses.

25. The method of claim 24, further comprising:
forming the oxide fill structures using an atomic layer deposition operation that forms an oxide fill having discontinuities in at least one of the uniform recesses.
